(19) United States
(12) Patent Application Publication
(10) Pub. No.: US 2024/0275345 A1
(43) Pub. Date: Aug. 15, 2024

(54) RECONFIGURABLE TRANSIMPEDANCE FILTER

(71) Applicant: QUALCOMM Incorporated, San Diego, CA (US)

(72) Inventors: Huan WANG, Irvine, CA (US); Ibrahim Ramez CHAMAS, Carlsbad, CA (US); Yosef MELAMED, Raanana (IL)

(21) Appl. No.: 18/470,158

(22) Filed: Sep. 19, 2023

Related U.S. Application Data
(60) Provisional application No. 63/485,105, filed on Feb. 15, 2023.

(51) Int. Cl. H03F 3/45; H03F 1/56; H04B 1/04

(52) U.S. Cl. CPC H03F 3/45183; H03F 1/56; H03F 3/45641; H04B 1/04; H03F 2200/294; H03F 2200/451

(57) ABSTRACT

Certain aspects of the present disclosure generally relate to a reconfigurable active filter and techniques for using such a filter. One example reconfigurable active filter may include an amplifier including: a first input stage coupled between an input of the amplifier and an output of the amplifier, and a second input stage selectively coupled between the input of the amplifier and the output of the amplifier. The reconfigurable active filter may also include at least two feedback paths selectively coupled between the input of the amplifier and the output of the amplifier.

### CROSS-REFERENCE TO RELATED APPLICATIONS

The present application for patent claims the benefit of priority to U.S. Provisional Patent Appl. No. 63/485,105, filed Feb. 15, 2023, which is hereby incorporated by reference herein in its entirety.

### BACKGROUND

### Field of the Disclosure

Certain aspects of the present disclosure generally relate to electronic components and, more particularly, to a reconfigurable active filter.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long-Term Evolution (LTE) system or a New Radio (NR) system). Wireless devices may include a transceiver for processing signals for reception or transmission. A transmitter and/or a receiver in such a transceiver may include one or more oscillators, one or more amplifiers, and one or more filters.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards a reconfigurable active filter. The reconfigurable active filter generally includes an amplifier including: a first input stage coupled between an input of the amplifier and an output of the amplifier; and a second input stage selectively coupled between the input of the amplifier and the output of the amplifier. The reconfigurable active filter also includes at least two feedback paths selectively coupled between the input of the amplifier and the output of the amplifier.

Certain aspects of the present disclosure are directed towards a method for signal processing. The method generally includes determining an operating mode of a wireless device having at least two feedback paths selectively coupled between an input of an amplifier and an output of the amplifier, and selectively coupling one or more of the at least two feedback paths between the input of the amplifier and the output of the amplifier based on the operating mode, the amplifier including: a first input stage coupled between the input of the amplifier and the output of the amplifier; and a second input stage selectively coupled between the input of the amplifier and the output of the amplifier.

Certain aspects of the present disclosure are directed towards an apparatus for signal processing. The apparatus generally includes means for determining an operating mode of a wireless device having at least two feedback paths selectively coupled between an input of an amplifier and an output of the amplifier, and means for selectively coupling one or more of the at least two feedback paths between the input of the amplifier and the output of the amplifier based on the operating mode, the amplifier including: a first input stage coupled between the input of the amplifier and the output of the amplifier; and a second input stage selectively coupled between the input of the amplifier and the output of the amplifier.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram of an example access point (AP) and example user terminals, in which aspects of the present disclosure may be practiced.

FIG. 3 is a block diagram of an example transceiver front end, in which aspects of the present disclosure may be practiced.

FIG. 4 illustrates an example reconfigurable active filter, in accordance with certain aspects of the present disclosure.

FIG. 5 illustrates an example reconfigurable active filter having an amplifier with a load and output stage shared between multiple amplifier paths, in accordance with certain aspects of the present disclosure.

FIG. 6 illustrates example input stages with circuitry for enabling and disabling the input stages, in accordance with certain aspects of the present disclosure.

FIG. 7 illustrates an example input stage having a common-mode stabilization capacitor and fast charging switches, in accordance with certain aspects of the present disclosure.

FIG. 8 is a flow diagram depicting example operations for signal processing, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward a reconfigurable active filter. The filter may include an amplifier having multiple amplifier paths and multiple feedback paths. Each of the feedback paths may be selectively coupled between an input and an output of the amplifier, for example, via an input-side switch and an output-side switch. Having both input-side and output-side switches prevents (or at least reduces) load sharing between feedback paths, as described in more detail herein. Similarly, each amplifier path may be selectively enabled or selectively coupled between the input and the output of the amplifier. The feedback path(s) and amplifier path(s) to be used for the filter may be selected based on one or more operating characteristics of a device (e.g., a wireless device), such as an operating mode, operating bandwidth, radio access technology (RAT), and/or whether narrow-band (NB) or wide-band (WB) operation is used. The different paths may be selected to meet specific communication specifications with respect to noise, linearity, and/or bandwidth, for example.

### Example Wireless Communications

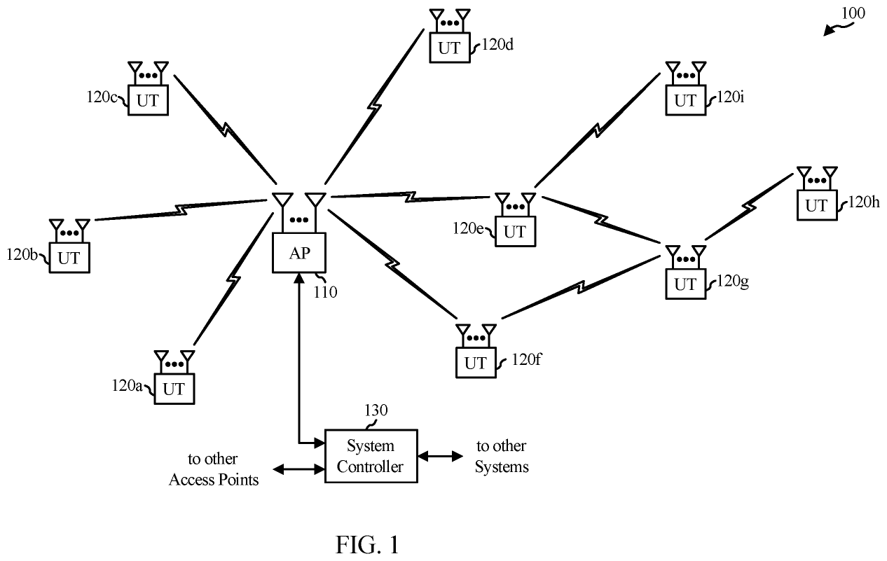

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point.

A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported). In some aspects, the user terminal 120 or access point 110 may include a reconfigurable active filter, as described in more detail herein.

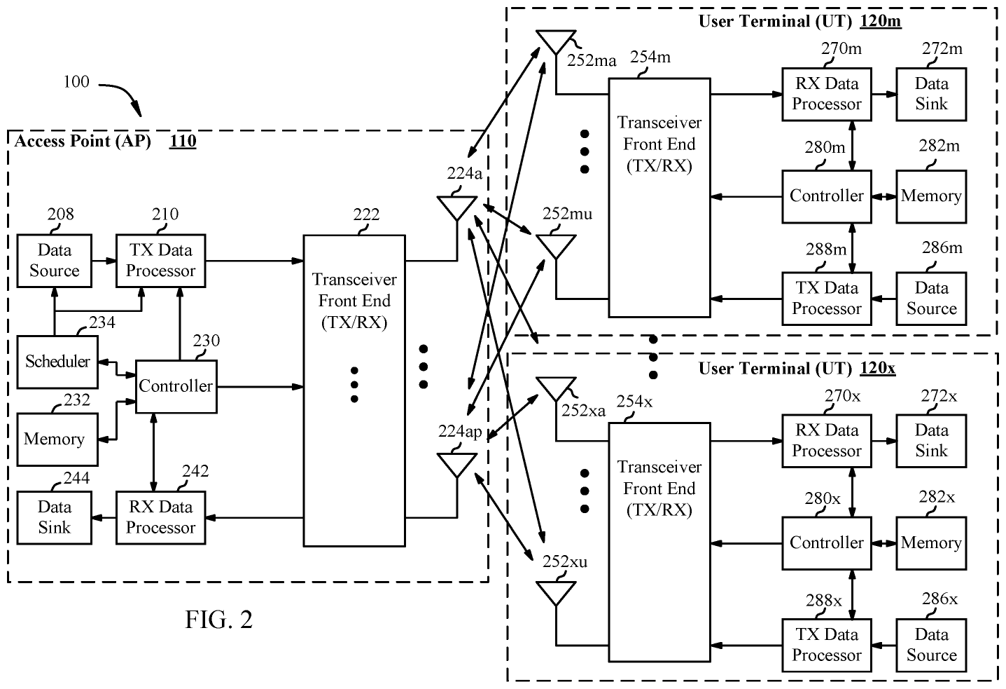

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ}for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. Decoded data for each user terminal or access terminal may be provided to a data sink (e.g., data sink 244, data sink 272m, or data sink 272x) for storage and/or a controller for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one or more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal. In some aspects, the transceiver front end 254 or 222 may include a reconfigurable active filter, as described in more detail herein.

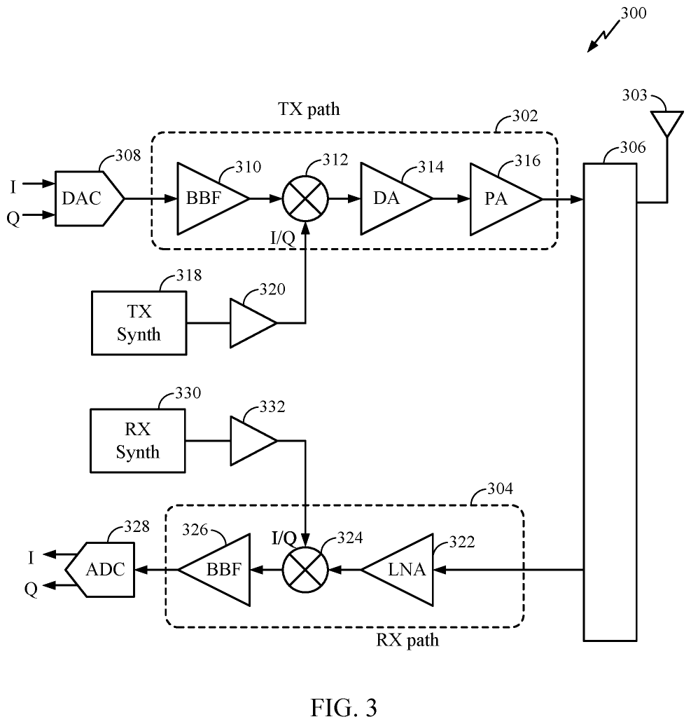

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a “transmit chain”) for transmitting signals via one or more antennas and a receive (RX) path 304 (also known as a “receive chain”) for receiving signals via the antennas. When the TX path 302 and the RX path 304 share an antenna 303, the paths may be connected with the antenna via an interface 306, which may include any of various suitable radio frequency (RF) devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC). In some cases, the PA 316 may be external to the RFIC.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequency of the signal of interest. The sum and difference frequencies are referred to as the “beat frequencies.” The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a received local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing. In some aspects, at least one of the BBF 310 or BBF 326 may be implemented as a reconfigurable active filter, as described in more detail herein.

While it is desirable for the output of an LO to remain stable in frequency, tuning the LO to different frequencies typically entails using a variable-frequency oscillator, which may involve compromises between stability and tunability. Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324.

### Example Reconfigurable Transimpedance Filter

Certain aspects of the present disclosure are directed towards a radio frequency (RF) transmitter (TX) (or receiver (RX)) with multi-mode, multi-bandwidth (BW) support. Multi-component carrier (CC) aggregation and heavy digital pre-distortion (DPD) involve high instantaneous BW (e.g., up to 800 MHz for some base station transmitters), while also supporting low BW modes down to 5 MHz. Some aspects provide a baseband filter (BBF) providing multi-mode, multi-bandwidth support. In some aspects, the BBF may be implemented as a reconfigurable transimpedance filter (also referred to as a “reconfigurable active filter”), as described in more detail herein.

For transmission, the BBF (e.g., BBF 310 of FIG. 3) may follow (e.g., having an input coupled to) a current-mode DAC (e.g., DAC 308) to convert a current signal into the voltage domain and drive an up-conversion mixer (e.g., mixer 312), which allows for meeting linearity specifications for the transmitter. In some aspects, the BBF may be used for reception. For example, the BBF (e.g., BBF 326) may follow a mixer (e.g., mixer 324, such as a current-mode mixer) and generate a filtered signal provided to an analog-to-digital converter (ADC) (e.g., ADC 328). The BBF provided herein supports ultra-wide BW modes, and meets noise and linearity specifications for both time-division duplex (TDD) and low BW frequency-division duplex (FDD) modes in legacy and emerging fifth-generation (5G) New Radio (NR) bands, while providing device robustness and efficiency.

A transmitter for a base station may have more stringent specifications with respect to BW, noise (e.g., error vector magnitude (EVM)/in-band noise), and linearity as compared to some user equipment (UE) implementations. The range of programmable BWs for a base station transmitter may be higher as compared to some UEs. Various tradeoffs may exist when designing a transceiver. For example, a tradeoff may exist between FDD receive band noise (RxBn) and TDD wide BW linearity. The BBF described herein may achieve low RxBn in FDD and support wide BW TDD modes while meeting linearity specifications.

To meet low RxBn specifications, a relatively larger operational amplifier input device (e.g., input stage) may be used. However, the parasitic capacitance of this operational amplifier's input stage may inhibit wide BW operation in TDD. More current could be consumed to overcome the effect of the parasitic capacitance on wide BW operation in TDD, but this may reduce system efficiency and pose thermal issues. The feedback loop of the BBF may be unstable in wide BW mode. Therefore, the BBF may be implemented to push the dominant pole in wide BW modes to higher frequencies to achieve enough loop gain to meet linearity specifications. Large parasitic capacitance due to meeting low BW mode specifications may load nodes of the BBF, resulting in increased current consumption and degradation of stability margin.

The input stage of the BBF may be an input transconductance (Gm) stage, which may be large in area and have high current consumption to meet low flicker noise in low BW FDD modes and high gain in wide BW TDD modes. To meet low BW mode specifications, a large feedback capacitive element (C_{fb}) may be used to provide sufficient filtering, resulting in large parasitic capacitance at various input/output nodes of the BBF.

The large parasitic capacitance results in increased driving current and degrades stability margin in wide BW modes. Certain aspects provide a filter with multiple paths that can be selectively enabled, allowing the filter to be reconfigured to meet varying specifications across operating modes.

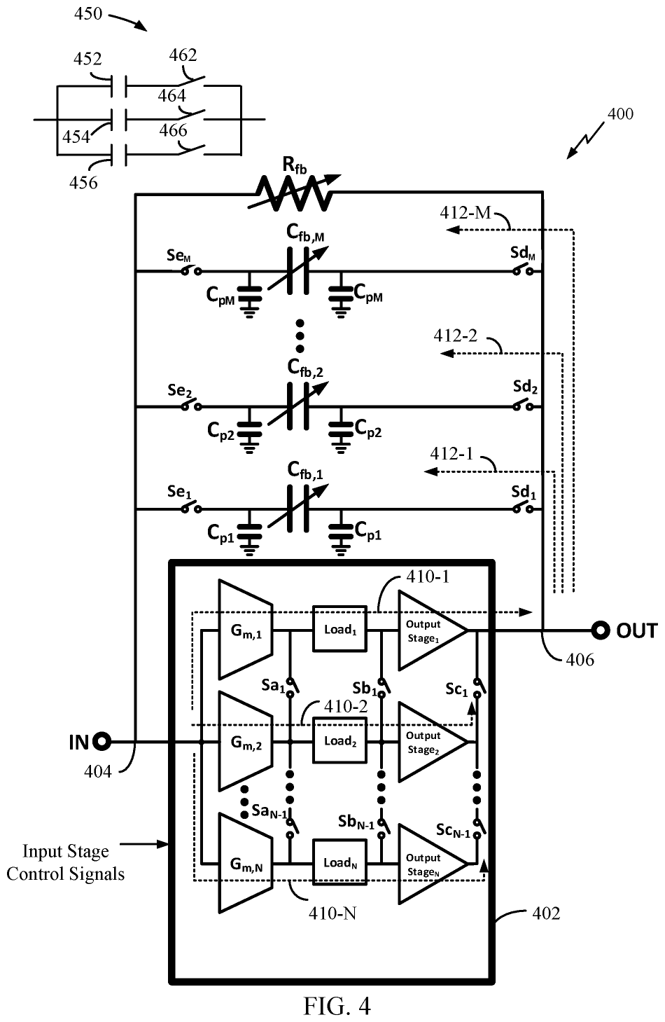

FIG. 4 illustrates a reconfigurable active filter 400 (also referred to as a “multi-path reconfiguration amplifier”), in accordance with certain aspects of the present disclosure. The filter 400 includes multiple paths to address varying design targets associated with different operating modes. For example, the amplifier 402 may include amplifier paths 410-1, 410-2, to 410-N (collectively referred to as amplifier paths 410), N being any integer greater than 1. The filter 400 may also include feedback paths 412-1, 412-2, to 412-M (collectively referred to as feedback paths 412), M being any integer greater than 1. Integer M may be equal to integer N, in some implementations. Integer M may be different than integer N, in other implementations. In other words, one feedback path may be associated with (e.g., used along with) more than one amplifier path.

The amplifier paths 410 and feedback paths 412 may be designed to meet various noise, BW, and linearity specifications for different operating modes (e.g., TDD/FDD, Global System for Mobile Communications (GSM), or Long-Term Evolution (LTE)). In some aspects, each of the amplifier paths (also referred to herein as signal paths) includes an input stage G_{m,1} to G_{m,N} (e.g., Gm stages G_{m,1} to G_{m,N}), a load (e.g., load₁ to load_{N}), and an output stage (e.g., output stage₁ to output stage_{N}). For each of the different operating modes (e.g., TDD/FDD, GSM, or LTE), one or more of the amplifier paths may be activated (e.g., enabled or coupled via switches between the input/output of the amplifier 402). For example, a first amplifier path may be dedicated to meeting a low-band (e.g., 50 MHz) specification of a specific operating mode, a second amplifier path may be dedicated to meeting a high-band (e.g., 800 MHz) specification of a specific operating mode, a third amplifier path may be dedicated to meeting a low-noise specification of a specific operating mode, and so on.

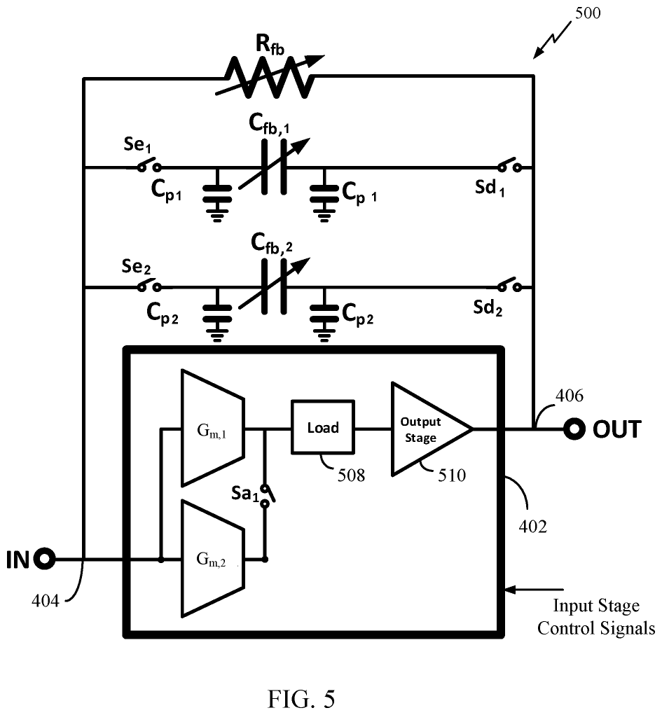

In some aspects, one or more of the loads or the output stages may be shared by a single amplifier path, as described more detail with respect to FIG. 5. For example, an output stage that is for WB operation may be shared with an amplifier path dedicated for NB operation. In some aspects, one or more of the amplifier paths 410 and/or one or more of the feedback paths 412 may be activated (e.g., combined or shared to boost efficiency).

The amplifier 402 may include switches sa₁to sa_{N-1} coupled between outputs of Gm stages G_{m,1} to G_{m, N}, switches sb₁ to sb_{N-1} coupled between outputs of load₁ to load_{N}, and switches sc₁ to sc_{N-1} coupled between outputs of output stage₁ to output stage_{N}. The switches may be used to select one or more of the amplifier paths 410 to be activated (e.g., incorporated in a path between the input and output of amplifier 402). In some aspects, one or more of the Gm stages may be enabled or disabled using control signaling (e.g., by turning on or off a tail current source of the Gm stage, as described in more detail herein).

As one example, the amplifier path 410-1 may be activated by opening switches sa₁ to sa_{N-1}, sb₁ to sb_{N-1}, and sc₁ to sc_{N-1}. Amplifier path 410-2 may be activated by closing switch sc₁ and opening all other switches shown in amplifier 402 of FIG. 4. Amplifier path 410-N may be activated by closing switch sc₁ to sc_{N-1} and opening all other switches.

In some aspects, one or more amplifier paths may be coupled between the input and output of the amplifier 402 by closing associated switches, while one or more input stages of one or more other amplifier paths are turned off. For example, to activate only amplifier path 410-2, only switch sc₁ may be closed while input stage G_{m,1} is turned off. To activate only amplifier path 410-3, only switches sc₁ and sc₂ may be closed while the input stages G_{m,1} and G_{m,2} are turned off, and so on.

In some aspects, a load or output stage may be shared by multiple input stages. For example, only switch sa₁may be closed so that both input stages G_{m,1} and G_{m,2} may be activated and are sharing load₁ and output stage₁. Similarly, only sb₁ may be closed so that both input stages G_{m,1} and G_{m,2} may be activated and are sharing output stage₁, but are not sharing load₁ and load₂.

Each of the feedback paths 412 may include a respective feedback capacitive element C_{fb,1} to C_{fb,M}, which may have a tunable capacitance to meet operating specifications. Increasing the tuning range of a feedback capacitive element C_{fb} may result in higher parasitic capacitance (e.g., represented by parasitic capacitive elements Cₚ₁ to C_{pM}) for that capacitive element. The tuning range of a feedback capacitive element C_{fb} for each feedback path may be limited in some aspects to avoid (or at least reduce) parasitic capacitance loading, improving filter efficiency and stability. In some aspects, a tunable resistive element R_{fb} may be coupled between the output 406 and the input 404, as shown.

As illustrated, the feedback paths 412 also include respective input-side switches se₁ to se_{M} and respective output-side switches sd₁ to sd_{M}. Having both input-side and output-side switches prevents (or at least reduces) load sharing between the feedback paths when one or more of the feedback paths are deactivated (e.g., where a deactivated feedback path is decoupled from amplifier input/output by opening respective switches).

Each of the feedback capacitive elements C_{fb,1} to C_{fb,M} may be tunable by using a capacitor bank, such as the capacitor bank 450. The capacitor bank 450 may be implemented with multiple capacitors (e.g., capacitors 452, 454, 456) that are selectively coupled in parallel by controlling respective switches 462, 464, 466. In some aspects, instead of including switches sd₁ to sd_{M} in the feedback paths 412, the switches of the capacitor banks may be used to implement the function of switches sd₁ to sd_{M}. For example, to decouple feedback capacitive element C_{fb,1} from the output 406, switches of the associated capacitor bank used to implement (and tune) feedback capacitive element C_{fb,1} may be opened. For instance, if capacitor bank 450 is used to implement capacitive element C_{fb,1}, switches 462, 464, 466 may be opened, decoupling capacitive element C_{fb,1} from the output 406.

In some aspects, amplifier paths may be provided for a narrow BW (NB) mode and a wide BW (WB) mode, as described in more detail with respect to FIG. 5. With NB and WB amplifier paths, stringent FDD noise specifications and TDD wide BW linearity specifications may be accommodated.

FIG. 5 illustrates a reconfigurable active filter 500 using an input stage G_{m,1} and an input stage G_{m,2}, in accordance with certain aspects of the present disclosure. In some aspects, input stage G_{m,1} may be used for NB operation, and input stage G_{m,2} may be used for WB operation. In other aspects, input stage G_{m,1} may be used for WB operation, and input stage G_{m,2} may be used for NB operation. Input stages G_{m,1} and G_{m,2} have inputs coupled to the input 404 of amplifier 402. In some aspects, the outputs of input stages G_{m,1} and G_{m,2} may be coupled to a load 508 and/or output stage 510. In some aspects, the output of input stage G_{m,2} may be selectively coupled to the load 508 via a switch sa₁. As described, the load 508 and output stage 510 may be shared by the input stages G_{m,1} and G_{m,2}. For example, since the contribution to noise may be dominated by the input stages, the input stages may share the same load and/or output stage.

In some aspects, the reconfigurable active filter 500 may include a feedback path having a feedback capacitive element C_{fb,1} and a feedback capacitive element C_{fb,2}. In some aspects, feedback capacitive element C_{fb,1} may be used for feedback capacitance when input stage G_{m,1} is active, and feedback capacitive element C_{fb,2} may be used for feedback capacitance when input stage G_{m,2} is active. The NB capacitor bank parasitic capacitance (e.g., parasitic capacitance of feedback capacitive element C_{fb,2} assuming that element C_{fb,2} is associated with NB operation) may be isolated from the output 406 via switch sd₁ to reduce the impact of the parasitic capacitance on WB operation.

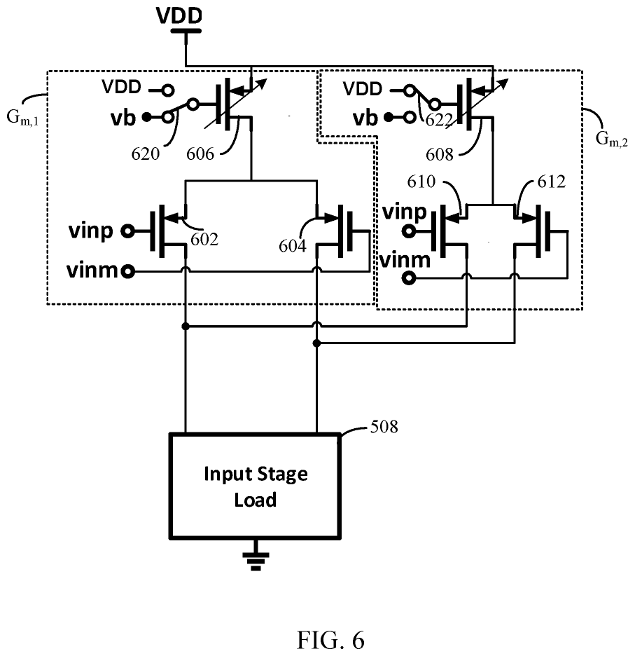

An input stage may be turned on or off by turning on or off the tail current source of the input stage (e.g., instead of using switch Sa₁ coupled between the Gm stage outputs). For example, each input stage may receive a control signal (e.g., labeled “input stage control signals”) for enabling or disabling the input stage by controlling a tail current source of the input stage, as described in more detail with respect to FIG. 6. To use only the input stage G_{m,2} in the amplifier path between the input 404 and output 406, switch Sa₁may be closed, and input stage G_{m,1} may be turned off.

FIG. 6 illustrates example circuitry used to implement input stages G_{m,1} and G_{m,2}, in accordance with certain aspects of the present disclosure. Input stage G_{m,1} may include an input transistor 602 having a gate receiving a positive input voltage (vinp) and an input transistor 604 having a gate receiving a negative input voltage (vinm). The positive input voltage vinp and the negative input voltage vinm form a differential input voltage for the input stage. The sources of input transistors 602, 604 are coupled to a tail current source (e.g., implemented using transistor 606). Similarly, input stage G_{m,2} may include an input transistor 610 having a gate receiving vinp and an input transistor 612 having a gate receiving vinm. The sources of input transistors 610, 612 are coupled to a tail current source (e.g., implemented using transistor 608). The sources of transistors 606, 608 are coupled to a voltage rail VDD. The drains of input transistors 602, 604, 610, 612 are coupled to the shared load 508, as shown.

In some aspects, the gates of transistors 606, 608 (e.g., used to implement the tail current sources) may be controlled to enable/disable a corresponding input stage. For example, to disable input stage G_{m,1}, the gate of transistor 606 may be coupled to VDD by controlling switch 620, deactivating transistor 606. Input stage G_{m,1} may be enabled by providing a bias voltage (vb) to the gate of transistor 606 (e.g., by controlling switch 620). Similarly, to disable input stage G_{m,2}, the gate of transistor 608 may be coupled to VDD by controlling switch 622, deactivating transistor 608. Input stage G_{m,2} may be enabled by providing the bias voltage (vb) to the gate of transistor 608. The switches 620, 622 may be controlled via control signaling, as described with respect to FIGS. 4 and 5.

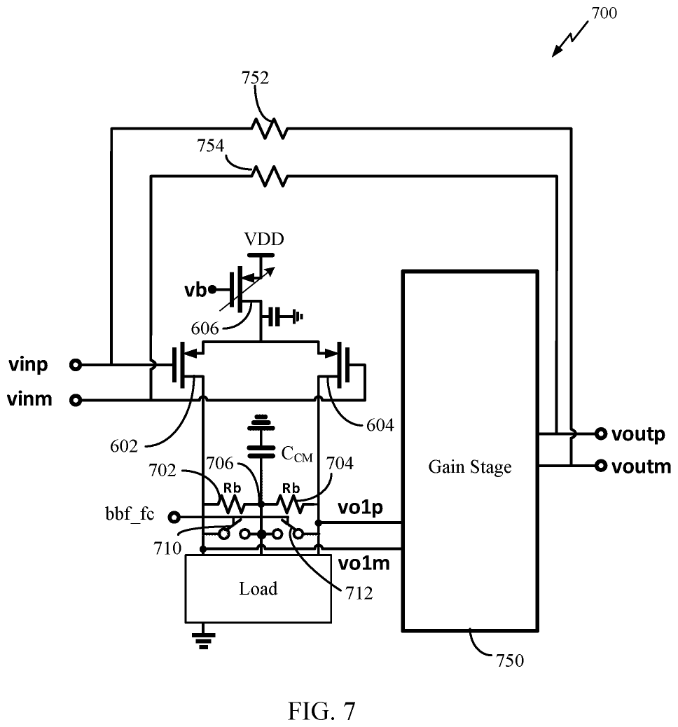

FIG. 7 is a circuit diagram illustrating an example input stage 700, in accordance with certain aspects of the present disclosure. The input stage 700 may be implemented with a common-mode (CM) stabilization capacitive element C_{CM} and fast charging switches to prevent (or at least reduce) shoot-through current at start-up. As shown, the input stage 700 includes a resistive element 702 coupled between a drain of input transistor 602 and a CM node 706, and a resistive element 704 coupled between a drain of input transistor 604 and the CM node 706. In some aspects, the CM stabilization capacitive element C_{CM} may be coupled between the CM node and a reference potential node (e.g., electrical ground) to reduce (e.g., suppress) high-frequency CM gain in the input stage.

In some aspects, fast charging switches may be used to rapidly charge C_{CM}, preventing (or at least reducing) high shoot-through current at start-up and improving reliability during power on/off operations of the filter. For example, the input stage 700 may include a fast charging switch 710 and a fast charging switch 712. The switches 710, 712 may be controlled via a baseband filter fast charge signal (labeled “bbf_fc”). The switches 710, 712 may be closed to short across resistive elements 702, 704, respectively, reducing the charge time of capacitive element C_{CM}. Once capacitive element C_{CM} is charged, the CM voltage at the CM node 706 may be set, and the switches 710, 712 may be opened. Capacitive element C_{CM} may not affect the differential-mode pole, may stabilize the CM loop, and may provide filtering of CM noise. As shown, the positive and negative output voltages vo1p, vo1m of the input stage 700 may be provided to a gain stage 750, in some aspects. As shown, in some aspects, a feedback resistive element 752 may be coupled between the voutm node and the vinp node of the input stage 700, and a feedback resistive element 754 may be coupled between the voutp node and the vinm node.

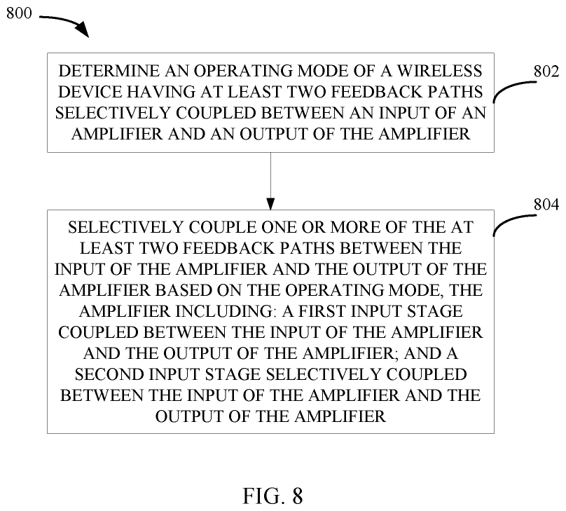

FIG. 8 is a flow diagram depicting example operations 800 for signal processing, in accordance with certain aspects of the present disclosure. For example, the operations 800 may be performed by a signal processing system including a filter, such as the reconfigurable active filter 400 or 500.

At block 802, the signal processing system determines an operating mode of a wireless device. The wireless device may include at least two feedback paths (e.g., feedback paths 412 of FIG. 4) selectively coupled between an input (e.g., input 404 of FIG. 4) of an amplifier (e.g., amplifier 402 of FIG. 4) and an output (e.g., output 406 of FIG. 4) of the amplifier. At block 804, the signal processing system selectively couples one or more of the at least two feedback paths between the input of the amplifier and the output of the amplifier based on the operating mode. In some aspects, the amplifier includes a first input stage (e.g., input stage G_{m,1} described with respect to FIG. 4 or FIG. 5) coupled between the input of the amplifier and the output of the amplifier, and a second input stage (e.g., input stage G_{m,2} described with respect to FIG. 4 or FIG. 5) selectively coupled between the input of the amplifier and the output of the amplifier.

The signal processing system may selectively couple, via one or more switches (e.g., switches sa₁to sa_{N-1} described with respect to FIG. 4), at least the second input stage between the input of the amplifier and the output of the amplifier based on the operating mode. The one or more switches may include a switch (e.g., switch sa₁) coupled between an output of the first input stage and an output of the second input stage.

In some aspects, the signal processing system selectively couples a load impedance (e.g., load₂) of the amplifier between an output of the second input stage and the output of the amplifier based on the operating mode. The signal processing system may also selectively couple an output stage (e.g., output stage₂) between the load impedance and the output of the amplifier based on the operating mode.

In some aspects, the signal processing system selectively enables the first input stage and the second input stage based on the operating mode. For example, the first input stage may include a first tail current source (e.g., transistor 606 described with respect to FIG. 6), the first input stage being selectively enabled by controlling the first tail current source. The second input stage may also include a second tail current source (e.g., transistor 608). The second input stage may be selectively enabled by controlling the second tail current source.

In some aspects, the signal processing system may selectively couple the at least two feedback paths between the input of an amplifier and the output of the amplifier by selectively coupling a first capacitive element (e.g., feedback capacitive element C_{fb,1}) in series between the input of the amplifier and the output of the amplifier, and selectively couple a second capacitive element (e.g., feedback capacitive element C_{fb,2}) in series between the input of the amplifier and the output of the amplifier. The signal processing system may selectively couple the first capacitive element by controlling a first switch (e.g., switch se₁ of FIG. 6) coupled between the input of the amplifier and the first capacitive element, and a second switch (e.g., switch sd₁ of FIG. 6) coupled between the first capacitive element and the output of the amplifier. The signal processing system may selectively couple the second capacitive element (e.g., feedback capacitive element C_{fb,2}) by controlling a third switch (e.g., switch se₂) coupled between the input of the amplifier and the second capacitive element, and a fourth switch (e.g., switch sd₂) coupled between the second capacitive element and the output of the amplifier. At least one of the first capacitive element or the second capacitive element may include a variable capacitive element.

In some aspects, the operating mode may include, represent, or indicate an operating bandwidth of a reconfigurable active filter. For example, the at least two feedback paths may be selectively coupled based on the operating bandwidth of the reconfigurable active filter being wide-band or narrow-band.

While some examples provided herein are described with respect to a filter implemented for a base station to facilitate understanding, the aspects of the present disclosure may be implemented for any suitable wireless device. For example, the filter described herein may be implemented in a transceiver of a UE, in some cases.

### Example Aspects

In addition to the various aspects described above, specific combinations of aspects are within the scope of the disclosure, some of which are detailed below:

Aspect 1. A reconfigurable active filter, comprising: an amplifier including: a first input stage coupled between an input of the amplifier and an output of the amplifier; and a second input stage selectively coupled between the input of the amplifier and the output of the amplifier; and at least two feedback paths selectively coupled between the input of the amplifier and the output of the amplifier.

Aspect 2. The reconfigurable active filter of aspect 1, wherein one or more of the at least two feedback paths are selectively coupled between the input of the amplifier and the output of the amplifier based on an operating mode of a wireless device.

Aspect 3. The reconfigurable active filter of any of aspects 1-2, wherein the first input stage includes a first transconductance amplifier, and wherein the second input stage includes a second transconductance amplifier.

Aspect 4. The reconfigurable active filter of any of aspects 1-3, wherein at least the second input stage is selectively coupled, via one or more switches, between the input of the amplifier and the output of the amplifier based on an operating mode of a wireless device.

Aspect 5. The reconfigurable active filter of aspect 4, wherein one or more of the at least two feedback paths are selectively coupled between the input of the amplifier and the output of the amplifier based on the operating mode.

Aspect 6. The reconfigurable active filter of any of aspects 4-5, wherein the one or more switches includes a switch coupled between an output of the first input stage and an output of the second input stage.

Aspect 7. The reconfigurable active filter of any of aspects 4-6, wherein the amplifier further comprises: a load impedance selectively coupled between an output of the second input stage and the output of the amplifier based on the operating mode; and an output stage selectively coupled between the load impedance and the output of the amplifier based on the operating mode.

Aspect 8. The reconfigurable active filter of any of aspects 1-7, wherein the first input stage and the second input stage are configured to be selectively enabled based on an operating mode of a wireless device.

Aspect 9. The reconfigurable active filter of aspect 8, wherein: the first input stage includes a first tail current source, the first input stage being configured to be selectively enabled by controlling the first tail current source; and the second input stage includes a second tail current source, the second input stage being configured to be selectively enabled by controlling the second tail current source.

Aspect 10. The reconfigurable active filter of any of aspects 1-9, wherein the first input stage comprises a common-mode (CM) capacitive element coupled between a CM node of the first input stage and a reference potential node.

Aspect 11. The reconfigurable active filter of aspect 10, wherein the first input stage further comprises: a first input transistor having a gate configured to receive a first input signal; a second input transistor having a gate configured to receive a second input signal; a first switch coupled between a drain of the first input transistor and the CM node; and a second switch coupled between a drain of the second input transistor and the CM node.

Aspect 12. The reconfigurable active filter of any of aspects 1-11, wherein the amplifier further comprises: a load impedance coupled between an output of the first input stage and the output of the amplifier; and an output stage coupled between the load impedance and the output of the amplifier.

Aspect 13. The reconfigurable active filter of any of aspects 1-12, wherein the at least two feedback paths include: a first feedback path including a first capacitive element selectively coupled in series between the input of the amplifier and the output of the amplifier; and a second feedback path including a second capacitive element selectively coupled in series between the input of the amplifier and the output of the amplifier.

Aspect 14. The reconfigurable active filter of aspect 13, wherein: the first feedback path includes a first switch coupled between the input of the amplifier and the first capacitive element and a second switch coupled between the first capacitive element and the output of the amplifier; and the second feedback path includes a third switch coupled between the input of the amplifier and the second capacitive element and a fourth switch coupled between the second capacitive element and the output of the amplifier.

Aspect 15. The reconfigurable active filter of any of aspects 13-14, wherein at least one of the first capacitive element or the second capacitive element comprises a variable capacitive element.

Aspect 16. The reconfigurable active filter of any of aspects 1-15, wherein the at least two feedback paths are selectively coupled between the input of the amplifier and the output of the amplifier based on an operating bandwidth of a reconfigurable active filter being wide-band or narrow-band.

Aspect 17. The reconfigurable active filter of any of aspects 1-16, wherein the reconfigurable active filter comprises a baseband filter coupled between a digital-to-analog converter (DAC) and a mixer.

Aspect 18. The reconfigurable active filter of any of aspects 1-17, wherein the reconfigurable active filter comprises a baseband filter coupled between a mixer and an analog-to-digital converter (ADC).

Aspect 19. A method for signal processing, comprising: determining an operating mode of a wireless device having at least two feedback paths selectively coupled between an input of an amplifier and an output of the amplifier; and selectively coupling one or more of the at least two feedback paths between the input of the amplifier and the output of the amplifier based on the operating mode, the amplifier including: a first input stage coupled between the input of the amplifier and the output of the amplifier; and a second input stage selectively coupled between the input of the amplifier and the output of the amplifier.

Aspect 20. The method of aspect 19, wherein the first input stage includes a first transconductance amplifier, and wherein the second input stage includes a second transconductance amplifier.

Aspect 21. The method of any of aspects 19-20, further comprising selectively coupling, via one or more switches, at least the second input stage between the input of the amplifier and the output of the amplifier based on the operating mode.

Aspect 22. The method of aspect 21, wherein the one or more switches includes a switch coupled between an output of the first input stage and an output of the second input stage.

Aspect 23. The method of any of aspects 21-22, further comprising:

selectively coupling a load impedance of the amplifier between an output of the second input stage and the output of the amplifier based on the operating mode; and selectively coupling an output stage between the load impedance and the output of the amplifier based on the operating mode.

Aspect 24. The method of any of aspects 19-23, further comprising selectively enabling the first input stage and the second input stage based on the operating mode.

Aspect 25. The method of aspect 24, wherein: the first input stage includes a first tail current source, the method including selectively enabling the first input stage by controlling the first tail current source; and the second input stage includes a second tail current source, method including selectively enabling the second input stage by controlling the second tail current source.

Aspect 26. The method of any of aspects 19-25, wherein selectively coupling the at least two feedback paths between the input of an amplifier and the output of the amplifier includes: selectively coupling a first capacitive element in series between the input of the amplifier and the output of the amplifier; and selectively coupling a second capacitive element in series between the input of the amplifier and the output of the amplifier.

Aspect 27. The method of aspect 26, wherein: selectively coupling the first capacitive element includes controlling a first switch coupled between the input of the amplifier and the first capacitive element, and a second switch coupled between the first capacitive element and the output of the amplifier; and selectively coupling the second capacitive element includes controlling a third switch coupled between the input of the amplifier and the second capacitive element, and a fourth switch coupled between the second capacitive element and the output of the amplifier.

Aspect 28. The method of any of aspects 26-27, wherein at least one of the first capacitive element or the second capacitive element comprises a variable capacitive element.

Aspect 29. The method of any of aspects 19-28, wherein the operating mode comprises an operating bandwidth of a reconfigurable active filter.

Aspect 30. The method of aspect 29, wherein the at least two feedback paths are selectively coupled based on the operating bandwidth of the reconfigurable active filter being wide-band or narrow-band.

Aspect 31. An apparatus for signal processing, comprising: means for determining an operating mode of a wireless device having at least two feedback paths selectively coupled between an input of an amplifier and an output of the amplifier; and means for selectively coupling one or more of the at least two feedback paths between the input of the amplifier and the output of the amplifier based on the operating mode, the amplifier including: a first input stage coupled between the input of the amplifier and the output of the amplifier; and a second input stage selectively coupled between the input of the amplifier and the output of the amplifier.

### Additional Considerations

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The apparatus and methods described in the detailed description are illustrated in the accompanying drawings by various blocks, modules, components, circuits, steps, processes, algorithms, etc. (collectively referred to as “elements”). The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering. For example, means for determining may include a controller, such as the controller 230 of FIG. 1. Means for selectively coupling may include one or more switches, such as one or more of input-side switches se₁ to se_{M} and one or more of output-side switches sd₁ to sd_{M}.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An apparatus comprising a reconfigurable active filter comprising:
an amplifier including:
a first input stage coupled between an input of the amplifier and an output of the amplifier; and
a second input stage selectively coupled between the input of the amplifier and the output of the amplifier; and
at least two feedback paths selectively coupled between the input of the amplifier and the output of the amplifier.

2. The apparatus of claim 1, wherein one or more of the at least two feedback paths are selectively coupled between the input of the amplifier and the output of the amplifier based on an operating mode of a wireless device.

3. The apparatus of claim 1, wherein the first input stage includes a first transconductance amplifier, and wherein the second input stage includes a second transconductance amplifier.

4. The apparatus of claim 1, wherein at least the second input stage is selectively coupled, via one or more switches, between the input of the amplifier and the output of the amplifier based on an operating mode of a wireless device.

5. The apparatus of claim 4, wherein one or more of the at least two feedback paths are selectively coupled between the input of the amplifier and the output of the amplifier based on the operating mode.

6. The apparatus of claim 4, wherein the one or more switches include a switch coupled between an output of the first input stage and an output of the second input stage.

7. The apparatus of claim 4, wherein the amplifier further comprises:
a load impedance selectively coupled between an output of the second input stage and the output of the amplifier based on the operating mode; and
an output stage selectively coupled between the load impedance and the output of the amplifier based on the operating mode.

8. The apparatus of claim 1, wherein the first input stage and the second input stage are configured to be selectively enabled based on an operating mode of a wireless device.

9. The apparatus of claim 8, wherein:
the first input stage includes a first tail current source, the first input stage being configured to be selectively enabled by controlling the first tail current source; and
the second input stage includes a second tail current source, the second input stage being configured to be selectively enabled by controlling the second tail current source.

10. The apparatus of claim 1, wherein the first input stage comprises a common-mode (CM) capacitive element coupled between a CM node of the first input stage and a reference potential node.

11. The apparatus of claim 10, wherein the first input stage further comprises:
a first input transistor having a gate configured to receive a first input signal;
a second input transistor having a gate configured to receive a second input signal;
a first switch coupled between a drain of the first input transistor and the CM node; and
a second switch coupled between a drain of the second input transistor and the CM node.

12. The apparatus of claim 1, wherein the amplifier further comprises:
a load impedance coupled between an output of the first input stage and the output of the amplifier; and
an output stage coupled between the load impedance and the output of the amplifier.

13. The apparatus of claim 1, wherein the at least two feedback paths include:
a first feedback path including a first capacitive element selectively coupled in series between the input of the amplifier and the output of the amplifier; and
a second feedback path including a second capacitive element selectively coupled in series between the input of the amplifier and the output of the amplifier.

14. The apparatus of claim 13, wherein:
the first feedback path includes a first switch coupled between the input of the amplifier and the first capacitive element and a second switch coupled between the first capacitive element and the output of the amplifier; and
the second feedback path includes a third switch coupled between the input of the amplifier and the second capacitive element and a fourth switch coupled between the second capacitive element and the output of the amplifier.

15. The apparatus of claim 13, wherein at least one of the first capacitive element or the second capacitive element comprises a variable capacitive element.

16. The apparatus of claim 1, wherein the at least two feedback paths are selectively coupled between the input of the amplifier and the output of the amplifier based on an operating bandwidth of a reconfigurable active filter being wide-band or narrow-band.

17. The apparatus of claim 1, wherein the reconfigurable active filter comprises a baseband filter coupled between a digital-to-analog converter (DAC) and a mixer.

18. The apparatus of claim 1, wherein the reconfigurable active filter comprises a baseband filter coupled between a mixer and an analog-to-digital converter (ADC).

19. A method for signal processing, comprising:
determining an operating mode of a wireless device having at least two feedback paths selectively coupled between an input of an amplifier and an output of the amplifier; and
selectively coupling one or more of the at least two feedback paths between the input of the amplifier and the output of the amplifier based on the operating mode, the amplifier including:
a first input stage coupled between the input of the amplifier and the output of the amplifier; and
a second input stage selectively coupled between the input of the amplifier and the output of the amplifier.

20. The method of claim 19, wherein the first input stage includes a first transconductance amplifier, and wherein the second input stage includes a second transconductance amplifier.

21. The method of claim 19, further comprising selectively coupling, via one or more switches, at least the second input stage between the input of the amplifier and the output of the amplifier based on the operating mode.

22. The method of claim 21, wherein the one or more switches include a switch coupled between an output of the first input stage and an output of the second input stage.

23. The method of claim 21, further comprising:
selectively coupling a load impedance of the amplifier between an output of the second input stage and the output of the amplifier based on the operating mode; and
selectively coupling an output stage between the load impedance and the output of the amplifier based on the operating mode.

24. The method of claim 19, further comprising selectively enabling the first input stage and the second input stage based on the operating mode.

25. The method of claim 24, wherein:
the first input stage includes a first tail current source;
selectively enabling the first input stage comprises controlling the first tail current source;
the second input stage includes a second tail current source; and
selectively enabling the second input stage comprises controlling the second tail current source.

26. The method of claim 19, wherein selectively coupling the at least two feedback paths between the input of the amplifier and the output of the amplifier includes:
selectively coupling a first capacitive element in series between the input of the amplifier and the output of the amplifier; and
selectively coupling a second capacitive element in series between the input of the amplifier and the output of the amplifier.

27. The method of claim 26, wherein:
selectively coupling the first capacitive element includes controlling a first switch coupled between the input of the amplifier and the first capacitive element, and a second switch coupled between the first capacitive element and the output of the amplifier; and
selectively coupling the second capacitive element includes controlling a third switch coupled between the input of the amplifier and the second capacitive element, and a fourth switch coupled between the second capacitive element and the output of the amplifier.

28. An apparatus for signal processing, comprising:
means for determining an operating mode of a wireless device having at least two feedback paths selectively coupled between an input of an amplifier and an output of the amplifier; and
means for selectively coupling one or more of the at least two feedback paths between the input of the amplifier and the output of the amplifier based on the operating mode, the amplifier including:
a first input stage coupled between the input of the amplifier and the output of the amplifier; and
a second input stage selectively coupled between the input of the amplifier and the output of the amplifier.
